(19) United States
(12) Patent Application Publication
(10) Pub. No.: US 2019/0165219 A1
(43) Pub. Date: May 30, 2019

(54) SUBSTRATE FOR OPTICAL DEVICE AND OPTICAL DEVICE PACKAGE HAVING THE SAME

(71) Applicant: POINT ENGINEERING CO., LTD., Asan (KR)

(72) Inventors: Bum Mo AHN, Suwon (KR); Seung Ho PARK, Hwaseong (KR); Tae Hwan SONG, Cheonan (KR)

(21) Appl. No.: 16/198,383

(22) Filed: Nov. 21, 2018

(30) Foreign Application Priority Data
Nov. 24, 2017 (KR) 10-2017-0158591

(51) Int. Cl. H01L 33/48; H01L 33/62; H01L 33/52; H01L 33/58

(52) U.S. Cl. CPC H01L 33/486; H01L 33/58; H01L 33/52; H01L 33/62

(57) ABSTRACT

Disclosed is a substrate for an optical device. The substrate has a cavity for mounting an optical element. The cavity has a sloped wall surface having a surface roughness Ra controlled to fall within a range of 1 nm≤Ra≤100 nm, thereby increasing the surface reflectance inside the cavity in which the optical element is mounted and thus minimizing the loss of light emitted from the optical element. Further disclosed is an optical device package including the same substrate.

### CROSS REFERENCE TO RELATED APPLICATION

The present application claims priority to Korean Patent Application No. 10-2017-0158591, filed Nov. 24, 2017, the entire contents of which is incorporated herein for all purposes by this reference.

### BACKGROUND OF THE INVENTION

### Field of the Invention

The present invention relates to a substrate for an optical device (hereinafter, simply referred to as an optical device substrate) and an optical device package including the same. More particularly, the present invention relates to an optical device substrate having a sloped wall surface with an improved surface roughness to reduce light loss compared to conventional optical device substrates, and an optical device package including the same.

### Related Art

An optical device package refers to a package in which an optical device functioning to emit a light beam is mounted.

In this case, an optical device refers to a device that receives an electrical signal and generates a light beam in accordance with the electrical signal.

Among optical devices, a light emitting diode (LED) has advantages of having a higher luminous efficiency than other conventional optical devices generating high-intensity light. For these advantages, LEDs are now widely used in display devices.

An optical device package is prepared by mounting an optical device and other necessary parts on a substrate (hereinafter, referred to as an optical device substrate).

Korean Patent No. 10-1757197 (hereinafter, referred to as “Patent Document 1”) discloses a conventional optical device substrate on which an optical device can be mounted.

In Patent Document 1, the optical device substrate includes a conductive layer, an insulating later for electrically insulating the conductive layer, a cavity having a predetermined depth and formed in a region including the insulating layer, an optical element disposed at the center of the bottom of the cavity, and a lens covering the upper end of the cavity.

In the case of the optical device substrate disclosed in Patent Document 1, tool machining is performed to form the cavity extending through the insulating layer. The tool machining results in a cavity having a sloped wall surface with a high surface roughness which deteriorates the reflectivity of light.

Conventionally, in connection with the cavity structure disclosed in Patent Document 1, the surface roughness attributable to tool machining was not a big issue.

On the other hand, such an optical device substrate can be employed in a UV exposure apparatus that emits a UV light beam to transfer or print a specific pattern.

Korean Patent Application Publication No. 10-2017-0015075 (hereinafter, referred to as Patent Document 2) and Korean Patent Application Publication No. 10-2017-0029917 (hereinafter, referred to as Patent Document 3) disclose conventional UV exposure apparatuses.

According to Patent Document 2, the exposure apparatus includes an exposure glass substrate, an exposure table, a driving unit for moving the exposure table, an optical system, and an exposure light source module unit for emitting an exposure light beam, the module unit including a light source panel having a printed circuit board on which a plurality of ultraviolet (UV) light emitting elements is mounted in a matrix array form.

In Patent Document 2, exposure light emitted from the exposure light source module unit is condensed by the optical system, and the condensed light passes through a mask and impinges on the glass substrate. Thus, a pattern provided on the mask is transferred to the glass substrate. This process is called an exposure process.

According to Patent Document 3, the exposure apparatus includes an LED light source in which multiple LED chips, each including an array of LED elements, are mounted, a collimator for collimating UV beams, an integrator for improving the uniformity in the intensity of the UV beams (i.e., exposure light) passing through the collimator, thereby outputting uniform-intensity light beams, and a spherical mirror.

According to Patent Document 3, the exposure apparatus emits an exposure UV beam, thereby exposing and transferring a plurality of patterns formed in a mask onto a substrate.

For the exposure and pattern transfer, the apparatus disclosed in Patent Document 2 is required to secure a sufficient optical path for the light emitted from the exposure light source module unit.

However, when the surface roughness of the sloped wall surface of the cavity is high, the surface reflectivity is reduced, thereby causing diffused reflection and shortening the optical path.

In the apparatus disclosed in Patent Document 3, the integrator that outputs the collimated light is required to secure a sufficiently long optical path to facilitate the transfer of the pattern to the substrate.

However, the apparatus disclosed in Patent Document 3 has the same problem as the apparatus disclosed in Patent Document 2. That is, the surface roughness of the sloped wall surface of the cavity formed in the substrate lowers the reflectivity, resulting in diffused reflection, leading to a decrease in the optical path.

Therefore, to employ an optical device substrate in such an exposure apparatus, the structure of the optical device substrate needs to be improved in terms of an optical path without causing the loss of UV light.

The foregoing is intended merely to aid in the understanding of the background of the present invention, and is not intended to mean that the present invention falls within the purview of the related art that is already known to those skilled in the art.

### DOCUMENT OF RELATED ART

(Patent Document 1) Korean Patent No. 10-1757197.
(Patent Document 2) Korean Patent Application Publication No. 10-2017-0015075.
(Patent Document 3) Korean Patent Application Publication No. 10-2017-0029917.

### SUMMARY OF THE INVENTION

The present invention has been made in view of the problems occurring in the related arts and an objective of the present invention is to provide an optical device substrate being capable of minimizing the loss of light by decreasing the surface roughness of a sloped wall surface of a cavity formed in the optical device substrate, and an optical device package including the same.

Another objective of the present invention is to provide an optical device substrate suitable for use in an UV exposure apparatus and an optical device package including the same substrate.

In order to accomplish one objective of the present invention, according to one aspect of the present invention, there is provided an optical device substrate including: first and second metal members; a resin insulating layer disposed between the first metal member and the second metal member in a transverse direction to electrically insulate the first metal member and the second metal member from each other; an optical element cavity, in which a sloped wall surface of the cavity has a surface roughness Ra within a range of 1 nm≤Ra≤100 nm.

A lower portion of the optical device substrate may be formed such that a transverse cross section thereof decreases toward a lower end of the optical device substrate.

According to another aspect, there is provided an optical device substrate including: first and second metal members; a vertical insulating layer disposed between the first metal member and the second metal member in a transverse direction to electrically insulate the first metal member and the second metal member from each other; and an optical element cavity having a sloped wall covered with an insulating layer and a metal reflective layer provided on the insulating layer.

According to a further aspect of the present invention, there is provided an optical device substrate including: first and second metal members; a vertical insulating layer disposed between the first metal member and the second metal member in a transverse direction to electrically insulate the first metal member and the second metal member from each other; an optical element cavity having a sloped wall, in which an upper portion of the optical element cavity has a rectangular transverse cross section and a lower portion of the optical element cavity has a circular transverse cross section.

The upper portion and the lower portion of the optical element cavity have a surface roughness Ra within a range of 1 nm≤Ra≤100 nm.

In order to accomplish another objective of the present invention, according to another aspect of the present invention, there is provided an optical device package including: an optical device substrate including first and second metal members, a vertical insulating layer disposed between the first metal member and the second metal member in a transverse direction to electrically insulate the first metal member and the second metal member from each other, and an optical element cavity; an optical element mounted inside the optical element cavity; and a light transmitting member covering an opening of the optical element cavity, in which a sloped wall of the optical element cavity has a surface roughness within a range of 1 nm≤Ra≤100 nm.

The optical device substrate according to the present invention and the optical device package including the same substrate have advantages described below.

The optical device substrate according to the present invention and the optical device package including the same substrate can reduce the diffused reflection by minimizing the surface roughness of the sloped wall surface that defines the optical element cavity that is a cavity in which an optical element is to be mounted. Thus, when the optical device package according to the present invention is employed in a WUV exposure optical apparatus, it is possible to reduce the diffused reflection, thereby minimizing the loss of WUV light, ensuring a sufficient WUV optical path, and achieving effective WUV light condensation.

Therefore, the optical device package according to the present invention has an increased light efficiency because the sloped wall surface of the optical element cavity has a surface roughness that satisfies a condition under which the loss of light can be minimized.

In addition, the optical device substrate according to the present invention is structured such that the transverse cross section of the optical device substrate decreases toward the lower end thereof. Therefore, when a plurality of optical device packages is mounted to form a light source module, since the footprint (the area of the bonding surface) of the optical device packages can be reduced, the optical device packages can be more densely arranged.

Further, since the optical device substrate has an insulating layer in the lower portion thereof, when a plurality of optical device packages is arranged, the insulating layer functions as a space for accommodating an adhesive applied to the bottom surface of the optical device substrates, thereby preventing a short circuit.

In addition, the optical device substrate according to the present invention includes the insulating layer and the metal reflective layer provided on the sloped wall surface of the optical element cavity, thereby eliminating a hindering factor in reflectance to increase the reflectivity of the surface of the optical element cavity.

In addition, according to the present invention, the upper portion and the lower portion of the optical element cavity have different forms, thereby effectively condensing and outputting the light emitted from an optical element. This results in elimination of a shaded region.

### BRIEF DESCRIPTION OF THE DRAWINGS

The above and other objects, features and other advantages of the present invention will be more clearly understood from the following detailed description when taken in conjunction with the accompanying drawings, in which:

FIG. 1A is a cross-sectional view taken along a line IA-IA′ of FIG. 1B illustrating an optical device substrate according to a first preferred embodiment of the present invention;

FIG. 1B is a perspective view illustrating the optical device substrate according to the first preferred embodiment of the present invention;

FIG. 2A is a cross-sectional view taken along a line IIA-IIA′ of FIG. 2B illustrating an optical device substrate according to a second preferred embodiment of the present invention;

FIG. 2B is a perspective view of the optical device substrate according to the second preferred embodiment of the present invention;

FIG. 3A is a cross-sectional view taken along a line IIIA-IIIA′ of FIG. 3B;

FIG. 3B is a perspective view illustrating an optical device substrate according to a third preferred embodiment of the present invention;

FIG. 3C is a cross-sectional view taken along a line IIIC-IIIC′ of FIG. 3B;

FIG. 4 is a diagram illustrating the optical device substrate provided with an insulating member, according to the third preferred embodiment of the present invention;

FIG. 5 is a cross-sectional view of an optical device package including the optical device substrate of the first preferred embodiment of the present invention;

FIG. 6A is a photograph illustrating a state in which the surface roughness of the sloped wall surface of an optical device cavity formed in a conventional optical device substrate is measured with a surface roughness tester; and

FIG. 6B is a photograph illustrating a state in which the surface roughness of the sloped wall surface of an optical device cavity formed in an optical device substrate according to the present invention is measured with a surface roughness tester.

### DETAILED DESCRIPTION OF THE DISCLOSURE

Prior to describing optical device substrates according to first to fourth preferred embodiments of the present invention and optical device packages including the respective optical device substrates, terms used herein will be defined first. The term “light” refers to light emitted from a light-emitting element. The light may be ultraviolet (UV) rays when the optical device substrate or the optical device package according to the present invention is employed in a UV exposure apparatus.

In addition, the term “optical device package” refers to a device configured in a manner that a light-emitting element and a light-transmitting member are mounted on an optical device substrate to emit light.

Herein below, preferred embodiments of the invention will be described in detail with reference to the accompanying drawings.

Optical Device Substrate 1 According to First Preferred Embodiment

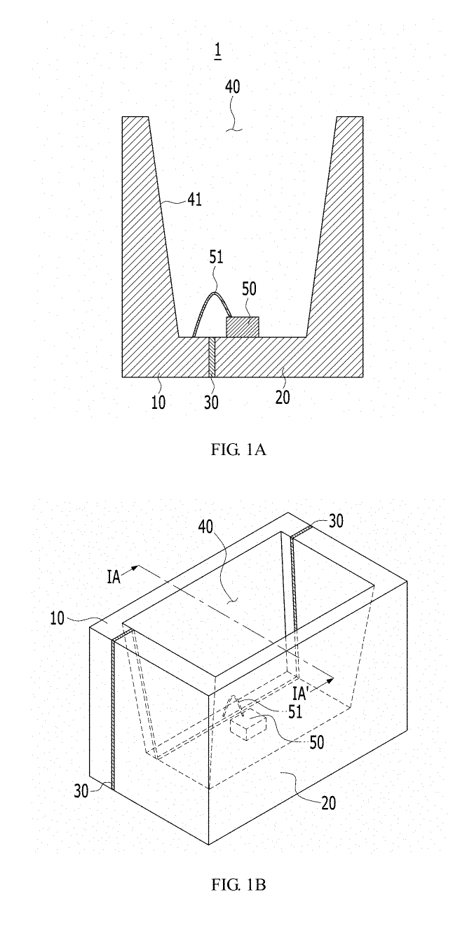

First, a substrate (hereinafter, referred to as an optical device substrate) 1 for an optical device, according to a first preferred embodiment of the present invention, will be described below with reference to FIGS. 1A and 1B.

FIG. 1A is a cross-sectional view taken along a line IA-IA′ of FIG. 1B illustrating an optical device substrate according to the first preferred embodiment of the present invention. FIG. 1B is a perspective view illustrating the optical device substrate according to the first preferred embodiment of the present invention.

Referring to FIG. 1, according to the first preferred embodiment, the optical device substrate 1 includes: a first metal member 10; a second metal member 20; a vertical insulating layer 30 disposed between the first metal member 10 and the second metal member 20 in a transverse direction to electrically insulate the first metal member 10 and the second metal member 20 from each other, and a cavity (hereinafter, referred to as an optical element cavity) 40 for mounting an optical element.

The optical device substrate 1 includes the first and second metal members 10 and 20. The optical device substrate 1 further includes the vertical insulating layer 30 disposed between the first metal member 10 and the second metal member 20 in the transverse direction to electrically insulate the first metal member 10 and the second metal member 20 from each other.

In the optical device substrate 1 according to the first preferred embodiment of the present invention, the first metal member 10, the vertical insulating layer 30, and the second metal member 20 are arranged in this order from the left side to the right side. The widths (lateral sizes) of the first and second metal members 10 and 20 are larger than the width (lateral size) of the vertical insulating layer 20. This design is advantageous in terms of effective heat dissipation.

The vertical insulating layer 20 is a vertically extending layer. The front end, rear end, upper end, and lower end of the vertical insulating layer 30 are exposed on the front surface, rear surface, upper surface, and lower surface of the optical device substrate 1, respectively.

The first metal member 10 is disposed on a first side (for example, left side) of the vertical insulating layer 30.

On the other hand, the second metal member 20 is disposed on a second side (for example, right side) of the vertical insulating layer 30, in which the first side and the second side are opposite to each other. As such, the first metal member 10 and the second metal member 20 are electrically isolated by the vertical insulating layer 30, and are connected to opposite polarity electrodes, respectively.

The first metal member 10 and the second metal member 20 are made of any one element selected from the group consisting of aluminum, aluminum alloys, copper, copper alloys, iron, iron alloys, and equivalents thereof. However, the materials of the first metal member 10 and the second metal member 20 are not limited thereto. The first metal member 10 and the second metal member 20 are connected to the opposite-polarity electrodes so that different polarity charges are supplied to a light-emitting element 50 mounted inside the optical element cavity 40 via the first metal member 10 and the second metal member 20, respectively.

The vertical insulating layer 30 is made of a material selected from the group consisting of Benzo Cyclo Butene (BCB), BismaleimideTrizine (BT), Poly Benz Oxazole (PBO), Polylmide (PI), phenolicresin, epoxy, silicone, and equivalents thereof. However, the material of the vertical insulating layer 30 is not limited thereto. The vertical insulating layer 30 includes an anodic aluminum oxide film when the first metal member 10 and the second metal member 20 are made of aluminum or an aluminum alloy.

The top surface side of the optical device substrate 1 is provided with the optical element cavity 40 in which an optical element is to be mounted. That is, the optical element cavity 40 has an open upper end.

The light-emitting element 50 is mounted in the optical element cavity 40.

In addition, the optical element cavity 40 is formed such that a sloped wall surface 41 defining the optical element cavity 40 is tapered to the bottom, and the optical element cavity 40 has a planar bottom.

The sloped wall surface 41 of the optical element cavity 40 reflects the light emitted from the light-emitting element 50.

Therefore, the optical element cavity 40 has a predetermined depth and a slope being determined such that the light emitted from the light-emitting element 50 can be reflected at an angle ensuring effective condensation of the light.

In other words, the sloped wall surface of the optical element cavity 40 is formed to have a suitable inclination angle and depth at which the light can be reflected at an appropriate angle to be effectively condensed through the reflection.

On the other hand, the surface roughness Ra of the sloped wall surface 41 of the optical element cavity 40 is within a range of 1 nm≤Ra≤100 nm.

In this case, the surface roughness Ra within the range of 1 nm≤Ra≤100 nm means the average value of the surface roughness Ra of each unit area of the sloped wall surface 41. Since the surface roughness Ra of the sloped wall surface 41 is within the range of 1 nm≤Ra≤100 nm, the light emitted from the light-emitting element 50 can be effectively reflected.

For example, when the optical device substrate 1 according to the present invention is employed in a UV exposure apparatus, it is preferred that a UV optical path is as long as possible. The UV optical path is affected by the surface roughness Ra of the sloped wall surface 41 of the optical element cavity 40.

In more detail, the optical device substrate 1 according to the present invention has the optical element cavity 40 in which to mount an optical element. The optical element cavity 40 needs to be designed such that the sloped wall surface 41 of the optical element cavity 40 has an inclination angle and a depth to ensure a light reflection angle by which the light emitted from the light-emitting element 50 can be effectively condensed.

When the optical device substrate 1 having the optical element cavity 40 is used in a UV exposure apparatus, when the surface roughness of the sloped wall surface 41 of the optical element cavity 40 is high, the surface reflectance is lowered. Furthermore, a high surface roughness causes diffused reflection (irregular reflection), thereby shortening a UV optical path.

Therefore, the surface roughness Ra of the sloped wall surface 41 of the optical element cavity 40 needs to be lowered to increase the surface reflectance and the UV optical path needs to be sufficiently long. With this configuration, it is possible to minimize the loss of UV light attributable to high surface roughness.

The reduction in the loss of UV light can be achieved when the surface roughness Ra of the sloped wall surface 41 of the optical element cavity 40 is within the range of 1 nm≤Ra≤100 nm.

In order for the surface roughness Ra of the sloped wall surface 41 of the optical element cavity 40 to fall within the range of 1 nm≤Ra≤100 nm, precision tool machining is performed. That is, the sloped wall surface 41 of the optical element cavity 40 can be obtained through precision tool machining such as polishing, electrolytic polishing, or sputtering. Such precision tool machining is performed until the surface roughness Ra is reduced to fall within the range of 1 nm≤Ra≤100 nm.

When an optical device package 100 is manufactured by using the optical device substrate 1 described above, since the surface roughness Ra of the sloped wall surface 41 of the optical element cavity 40 of the optical device substrate 1 is controlled to minimize the loss of light, the light efficiency of the optical device package 100 can be increased.

In the present embodiment, the optical element cavity 40 of the optical device substrate 1 has a rectangular transverse cross section. However, the transverse cross section of the optical element cavity 40 of the optical device substrate 1 may have a chamfered rectangular shape or a corner-rounded rectangular shape.

When the multiple optical device substrates 1 are arranged in the form of a grid, light beams emitted from optical devices elements mounted on the optical device substrates 1 are likely to partially overlap each other in some cases. When the optical element cavities 40 have a rectangular transverse cross section, it is possible to prevent the light beams emitted from the adjacent optical devices from overlapping, thereby eliminating a concern of occurrence of a shaded region.

On the other hand, when there is no concern for occurrence of a shaded region, that is, in a case where the optical device substrate 1 is used to manufacture a discrete optical device or a case where it is not necessary to densely arrange the multiple optical device substrates 1 within a small region, the transverse cross section of the optical element cavity 40 may be circular.

Optical Device Substrate 1′ According to Second Preferred Embodiment

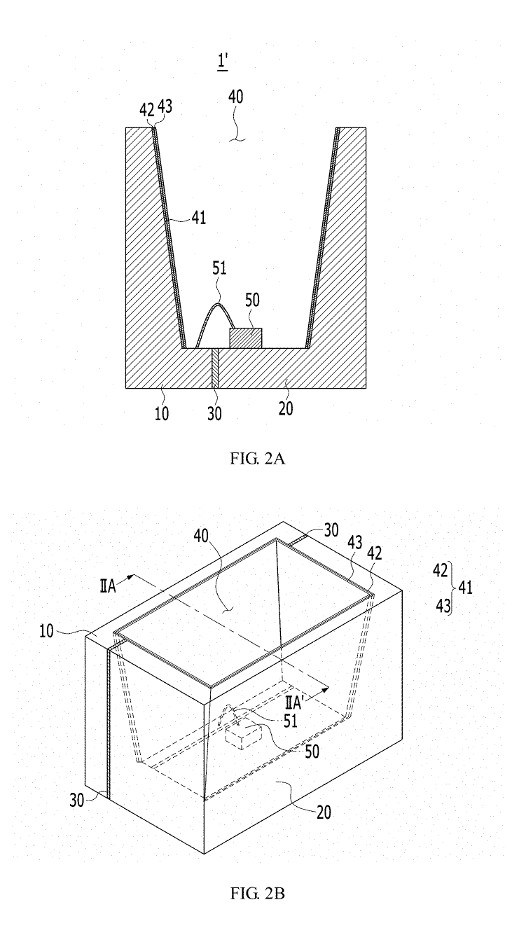

Herein below, an optical device substrate 1′ according to a second preferred embodiment of the present invention will be described with reference to FIGS. 2A and 2B. The optical device substrate 1′ according to the second preferred embodiment of the present invention is identical to the optical device substrate 1 according to the first preferred embodiment of the present invention except for an insulating layer 42 and a metal reflective layer 43 which is provided in a stacked manner on a sloped wall surface 41 of an optical element cavity 40. In describing the second preferred embodiment, the same elements as those in the first preferred embodiment are denoted by the same reference numerals and a detailed description of those elements will be omitted because the details of those elements can be understood by referring to the description of the first preferred embodiment.

FIG. 2A is a cross-sectional view taken along a line IIA-IIA′ of FIG. 2B illustrating the optical device substrate 1′ according to the second preferred embodiment of the present invention. FIG. 2B is a perspective view illustrating the optical device substrate 1′ according to the second preferred embodiment of the present invention.

As illustrated in FIGS. 2A and 2B, the optical device substrate 1′ includes: first and second metal members 10 and 20; a vertical insulating layer 30 disposed between the first metal member 10 and the second metal member 20 in a transverse direction to electrically insulate the first metal member 10 and the second metal member 20 from each other; an optical element cavity 40; an insulating layer 42; and a metal reflective layer 43.

The first metal member 10 and the second metal member 20 are made of a conductive material such as a metal to supply an electrical current to a light-emitting element 50 mounted in the optical element cavity 40. Specifically, the first metal member 10 and the second metal member 20 are made of aluminum or an aluminum alloy.

The vertical insulating layer 30 is made of a material selected from the group consisting of Benzo Cyclo Butene (BCB), BismaleimideTrizine (BT), Poly Benz Oxazole (PBO), Polylmide (PI), phenolicresin, epoxy, silicone, and equivalents thereof. However, the material of the vertical insulating layer 30 is not limited thereto.

The optical device substrate 1′ is provided with the optical element cavity 40 that is recessed from the top surface of the optical device substrate 1′. That is, the optical element cavity 40 has an open upper end.

In this case, since the vertical insulating layer 30 is exposed on the sloped wall surface 41 of the optical element cavity 40, there is a likelihood that the exposed portion of the vertical insulating layer 30 hinders reflection of light.

Thus, according to the second preferred embodiment of the present invention, the insulating layer 42 and the metal reflective layer 43 are sequentially formed on the sloped wall surface of the optical element cavity 40. Thus, this embodiment eliminates a light reflection-hindering factor by forming the insulating layer 42 and the metal reflective layer 43, thereby improving the surface reflectance of the surface of the optical element cavity 40.

More specifically, as illustrated in FIGS. 2A and 2B, the insulating layer 42 is formed on the sloped wall surface 41 that defines the optical element cavity 40. The insulating layer 42 is formed to cover the sloped wall surface 41 of the optical element cavity 40 and the upper end of the vertical insulating layer 30 exposed on the sloped wall surface.

In addition, the insulating layer 42 has a minimum requisite insulation performance to prevent a short circuit between the sloped wall surface 41 of the optical element cavity 40 and the metal reflective layer 43. The insulating layer 42 also functions as an adhering layer for aiding adhesion between the sloped wall surface 41 of the optical element cavity 40 and the metal reflective layer 43.

The insulating layer 42 is made of a polymer, a resin material, or an insulating material such as TaOx or TiOx. When the insulating layer 42 is made of a resin material, it is preferably formed by a coating process. On the other hand, when the insulating layer 42 is made of TaOx or TiOx, it is preferably formed by a deposition process.

The metal reflective layer 43 is formed on the insulating layer 42.

The metal reflective layer 43 is made of a pure metal having a high reflectivity. For example, when the light-emitting element emits light within a UV wavelength region, the metal reflective layer 43 is preferably made of pure aluminum (Al). On the other hand, when the light-emitting element emits light within a visible light wavelength region, the metal reflective layer 43 is preferably made of pure silver (Ag). When the light emitting element emits light within an infrared (IR) wavelength region, the metal reflective layer 43 is preferably made of pure gold. That is, the material of the metal reflective layer 43 is selected depending on the light emitted from an optical element (i.e., light-emitting element) mounted inside the optical element cavity to obtain an optimum reflectivity.

When the insulating layer 42 and the metal reflective layer 43 are formed on the sloped wall surface 41, a masking process is performed in advance to protect the vertical insulating layer 30 formed in the bottom of the optical element cavity 40 and an electrical wiring of the optical element 50. After the insulating layer 32 and the metal reflective layer 43 are formed, a masking layer formed through the masking process is preferably removed.

According to the second preferred embodiment of the present invention, since the insulation layer 42 and the metal reflective layer 43 are sequentially formed on the sloped wall surface 41 of the optical element cavity 40 of the optical device substrate 1′, a light reflection hindering factor is eliminated and thus the surface reflectance of the sloped wall surface 41 of the optical element cavity 40 can be increased. Further, according to the present embodiment, it is possible to more easily achieve the surface roughness Ra within a range of 1 nm≤Ra≤100 nm by forming the metal reflective layer 43.

The optical device substrate 1′ according to the second preferred embodiment of the present invention can be achieved first by preparing the optical device substrate 1 according to the first preferred embodiment of the present invention and then by additionally forming the insulating layer 42 and the metal reflective layer 143 on the optical device substrate 1.

That is, the optical device substrate 1′ according to the second preferred embodiment of the present invention is an addition of the insulation layer 42 and the metal reflective layer 43 to the optical device substrate 1 according to the first preferred embodiment of present invention.

Therefore, it should be noted the details of the elements common among the first preferred embodiment and the second preferred embodiment can be understood by referring to the description of the first preferred embodiment.

In brief, the optical device substrate according to the second preferred embodiment of the present invention includes: the first and second metal members 10 and 20; the vertical insulating layer 30 disposed between the first metal member 10 and the second metal member 20 in a transverse direction to electrically insulate the first metal member 10 and the second metal member 20 from each other; the optical element cavity 40; the insulation layer 42, and the metal reflective layer 43.

In addition, the optical device substrate is provided with the optical element cavity 40, and the sloped wall surface of the optical element cavity 40 is formed to satisfy a condition of 1 nm≤Ra≤100 nm wherein Ra is a surface roughness.

On the sloped wall surface 41 of the optical element cavity 40, the insulating layer 42 and the metal reflective layer 43 are formed in this order.

In this case, since the insulating layer 42 and the metal reflective layer 43 are formed on the sloped wall surface 41 of the optical element cavity 40, the metal reflective layer 32 improves the surface roughness Ra of the sloped wall surface 41.

When the sloped wall surface 41 has a high surface roughness Ra, since the insulating layer 42 and the metal reflective layer 43 are formed conforming to the surface irregularities of the original sloped wall surface 41 of the optical element cavity 40, although the metal reflective layer 43 is formed of a pure metal having a high reflectivity, there is a possibility that the surface of the metal reflective layer 43 is not sufficiently smooth and thus has a reflectance lower than a required reflectance which can be achieved when the surface roughness Ra is within the range of 1 nm≤Ra≤100 nm.

Therefore, in order for the surface roughness Ra of the top layer (i.e., metal reflective layer 43) formed on the original sloped wall surface 41 of the optical element cavity 40 to fall within the range of 1 nm≤Ra≤100 nm, before forming the insulating layer 42 and the metal reflective layer 43, the original sloped wall surface 41 of the optical element cavity 40 undergoes precision tool machining so that the initial surface roughness of the sloped wall surface 41 can be adjusted. After that, the insulating layer 42 and the metal reflective layer 43 are formed on the machined sloped wall surface 41 of the optical element cavity 40. In this way, it is possible to increase the surface reflectance of the surface of the optical element cavity 40.

That is, according to the present embodiment, the surface reflectance of the optical element cavity 40 is increased due to the factors: the final surface of the sloped portion of the optical element cavity 40 has a surface roughness Ra satisfying the condition “1 nm≤Ra≤100 nm”, thereby achieving the required surface reflectance; the insulating layer 42 is formed to eliminate a light reflection hindering factor on the sloped wall surface 41 of the optical element cavity 40; and the metal reflective layer 43 made of a highly reflective material is formed on the sloped wall surface.

In other words, conditions for increasing the reflectance of the sloped wall surface 41 of the optical element cavity 40 are satisfied. That is, a condition in which the surface roughness Ra of the sloped wall surface 41 of the optical element cavity 40 is within the range of 1 nm≤Ra≤100 nm and a condition in which the insulating layer 42 and the metal reflective layer 43 are formed on the sloped wall surface 41 of the optical element cavity 40, are satisfied. Therefore, it is possible to obtain a sufficient surface reflectance.

In the present embodiment, the optical element cavity 40 of the optical device substrate 1′ has a rectangular transverse cross section. However, the transverse cross section of the optical element cavity 40 of the optical device substrate 1′ may have a chamfered rectangular shape or a corner-rounded rectangular shape.

When the multiple optical device substrates 1′ are arranged in the form of a grid, the light beams emitted from the optical elements mounted on the optical device substrates 1 are likely to partially overlap each other in some cases. When the optical element cavities 40 have a rectangular transverse cross section, it is possible to prevent the light beams emitted from the adjacent optical elements from overlapping, thereby eliminating a concern of occurrence of a shaded region.

On the other hand, when there is no concern for occurrence of a shaded region, that is, in a case where the optical device substrate 1′ is used to manufacture a discrete optical device or a case where it is not necessary to densely arrange the multiple optical device substrates 1′ within a small region, the transverse cross section of the optical element cavity 40 may have a circular shape.

Optical Device Substrate 1″ According to Third Preferred Embodiment

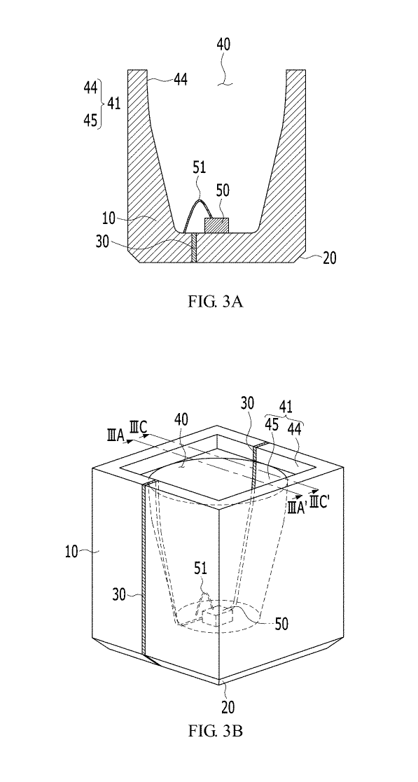

Herein below, an optical device substrate 1″ according to a third preferred embodiment of the present invention will be described with reference to FIGS. 3A and 3B. The optical device substrate 1″ according to the third preferred embodiment of the present invention is identical to the optical device substrate 1 of the first preferred embodiment or the optical device substrate 1′ of the second preferred embodiment, except for the shape of a sloped wall surface 41 defining an optical element cavity 40. Therefore, in describing the third preferred embodiment, the same elements as those in the first and second preferred embodiments are denoted by the same reference numerals, and a detailed description of those elements will be omitted here. The details of those elements can be understood by referring to the description of the first preferred embodiment or the second preferred embodiment.

FIG. 3A is a cross-sectional view taken along a line IIIA-IIIA of FIG. 3B illustrating an optical device substrate 1′ according to the third preferred embodiment of the present invention. FIG. 3B is a perspective view of the optical device substrate 1″ according to the third preferred embodiment of the present invention. FIG. 3C is a cross-sectional view taken along a line IIIC-IIIC′ of FIG. 3B.

As illustrated in FIG. 3A, the optical device substrate 1′ according to the third preferred embodiment includes: first and second metal members 10 and 20; a vertical insulating layer 30 disposed between the first metal member 10 and the second metal member 20 in a transverse direction to electrically insulate the first metal member 10 and the second metal member 20 from each other; and an optical element cavity 40.

The optical device substrate 1″ is provided with the optical element cavity 40 that is recessed from the top surface of the optical device substrate 1″. That is, the optical element cavity 40 has an open upper end.

The optical element cavity 40 is defined by a sloped wall surface 41. The sloped wall surface 41 includes an upper portion 44 and a lower portion 45. The upper portion 44 of the optical element cavity 40 having the sloped wall surface 41 has a rectangular transverse cross-sectional shape and the lower portion 45 of the optical element cavity 40 having the sloped wall surface 41 has a circular transverse cross sectional shape. Here, the upper portion 44 and the lower portion 45 of the sloped wall surface 41 function as reflective surfaces.

In greater detail, as illustrated in FIG. 3B, the upper portion 44 of the sloped wall surface 41 of the optical element cavity 40 formed in the optical device substrate 1″ according to the third preferred embodiment of the present invention has a rectangular transverse cross-sectional shape. That is, when the optical element cavity 40 is viewed from above, the optical device substrate 1″, the optical element cavity 40 has a rectangular opening. When the upper portion 44 of the optical element cavity 40, having a rectangular transverse cross-sectional shape, is formed by tool-machining, four corners of upper portion 44 of the optical element cavity 40 may be rounded, unlike the structure of FIG. 3B.

Herein below, the upper portion 44 of the sloped wall surface of the optical element cavity 40 is also referred to as an upper sloped wall surface 44.

On the other hand, as illustrated in FIG. 3B, the lower portion 45 of the sloped wall surface 41 of the optical element cavity 40 has a circular transverse cross sectional shape.

In more detail, the lower portion 45 of the sloped wall surface 41 of the optical element cavity 40 has a circular opening when the optical device substrate 1″ is viewed from above.

The bottom of the optical element cavity 40 has a circular flat floor shape. The lower portion 45 of the optical element cavity 40 is formed such that the circular transverse cross section thereof decreases with a depth of the optical element cavity 40, and the upper portion 44 of the optical element cavity 40 is formed to have a rectangular transverse cross section. When the optical device substrate 1″ according to the third preferred embodiment of the present invention is cut along a line IIIA-IIIA′, the cross-sectional shape illustrated in FIG. 3A is obtained.

In the optical element cavity 40, one side of the rectangular transverse cross-sectional shape of the upper portion 44 of the optical element cavity 40 preferably has the same size as the diameter of the circular transverse cross sectional shape of the lower portion 45 of the optical element cavity 40. In this case, the transverse cross section of the upper portion 44 of the optical element cavity 40 preferably has a square shape having four sides being equal in size.

As illustrated in FIG. 3B, the optical device substrate 1″ according to the third preferred embodiment of the present invention is preferably configured to have a rectangular transverse cross section. In the optical device substrate 1″, the upper portion 44 of the optical element cavity 40 has a rectangular transverse cross-sectional shape and the lower portion 45 of the optical element cavity 40 has a circular transverse cross sectional shape.

In the optical device substrate 1″ having the optical element cavity 40, when the size of each side of the square opening of the upper portion 44 of the optical element cavity 40 is equal to the diameter of the circular opening of the lower portion 45 of the optical element cavity, the upper sloped portion 44 and the lower sloped portion 45 can form a seamless continuous surface in a vertical direction.

Since the upper sloped portion 44 and the lower sloped portion 45 form a continuous surface in the vertical direction, the light emitted from the light-emitting element 50 can be more effectively reflected from the upper portion 44 of the sloped wall surface 41 of the optical element cavity 40.

FIG. 3A is a cross-sectional view illustrating the continuous sloped wall surface profile formed by the upper sloped portion 44 and the lower sloped portion 45. As illustrated in FIG. 3A, the upper sloped portion 44 and the lower slopped portion 45 form a continuous smooth sloped wall surface.

As to the optical device substrate 1″ according to the third preferred embodiment of the present invention, when the optical device substrate 1″ is viewed from above, the circular opening having a diameter having an equal size to each side of the square opening is inscribed in the square opening.

For example, it is assumed that an optical element cavity having a circular opening (circuit transverse cross section) is formed on an optical device substrate having a circular transverse cross section when the optical device substrate is viewed from above.

In this case, when multiple optical device packages 100 are arranged in an array form, since each of the optical device substrates has a circular shape (“O”), the optical device packages 100 are arranged in a pattern of “OOOO . . . OOO”. That is, a free space exists between each of the optical device packages 100.

From a different perspective, the light-emitting element 50 mounted inside the optical element cavity 40 emits light and the light reflects from the sloped wall surface 41 of the optical element cavity 40. In this case, the light reflects from the truncated conical wall surface of the optical element cavity because the optical element cavity has a truncated conical shape. Therefore, shaded regions occur between in the respective free spaces between the optical device packages.

However, since the optical device substrate 1″ according to the present invention has the optical element cavity 40 having a rectangular opening (a rectangular transverse cross section) at an upper portion thereof and a circular opening (a circular transverse cross section) at a lower portion thereof, it is possible to effectively condense the light emitted from the light-emitting element 50 within the optical element cavity 40. That is, it is possible to prevent shaded regions between optical device packages.

In addition, in the optical device substrate 1″ according to the present invention, the length of each side of the rectangular opening of the upper slopped portion 44 of the optical element cavity 40 is equal to the diameter of the circular opening of the lower sloped portion 45 of the optical element cavity 40. Therefore, it is possible to maximize a mounting area in which the light-emitting element 50 is mounted, thereby effectively condensing the light emitted from the light-emitting element 50.

For example, when it is assumed that an inclination angle of the lower sloped portion 45 of the optical element cavity 40 is 70°, since the length of each side of the rectangular opening of the upper sloped portion 44 is equal to the diameter of the circular opening of the lower sloped portion 45, the bottom floor of the lower sloped portion 45 of the optical element cavity 40 has a maximum area within a range allowed by the inclination angle of the sloped wall surface of 70°. That is, it is possible to best ensure the mounting area of the light-emitting element 45.

Meanwhile, in a case where the inclination angle of the lower sloped portion 45 is 70° and the length of the side of the rectangular opening of the upper sloped portion 44 is larger than the diameter of the circular opening of the lower sloped portion 45, the area of the circular opening (circular transverse cross section) of the lower sloped portion 45 of the optical element cavity 40 decreases with a depth to the bottom. Therefore, the diameter of the lower end (ending point in a depth direction) of the lower sloped portion 45 of the optical element cavity 40 is smaller than the diameter of the upper end (beginning point in the depth direction) of the lower sloped portion 45 of the optical element cavity 40.

In this case, since the diameter of the circular opening of the lower sloped portion 45 of the optical element cavity 40 is smaller than the length of each side of the rectangular opening of the upper sloped portion 44 of the optical element cavity 40, the area of the circular cross section (circular opening) of the upper end of the lower sloped portion 45 is smaller than that as in the case where the length of each side of the rectangular cross section (rectangular opening) of the upper sloped portion 44 of the optical element cavity 40 is equal to the diameter of the circular cross section (circular opening) of the lower sloped portion 45 of the optical element cavity 40. Accordingly, the diameter of the lower end (bottom floor) of the circular cross section of the lower sloped portion 45 is also smaller than that as in the case where the length of each side of the rectangular cross section (rectangular opening) of the upper sloped portion 44 of the optical element cavity 40 is equal to the diameter of the circular cross section (circular opening) of the lower sloped portion 45 of the optical element cavity 40. Therefore, the mounting area within which the light-emitting element 50 is mounted is reduced.

In conclusion, since the optical device substrate 1″ according to the present invention is structured such that the length of each side of the rectangular cross section (rectangular opening) of the upper sloped portion 44 of the optical element cavity 40 is set to be equal to the diameter of the circular cross section (circular opening) of the lower sloped portion 45 of the optical element cavity 40, the optical device substrate 1″ is advantageous in that the upper sloped portion 44 of the optical element cavity 40 improves the surface reflection and the lower sloped portion 45 maximizes the mounting area for the light-emitting element.

In the optical device substrate 1″ according to the present invention, the sloped wall of the optical element cavity 40 that is a cavity for mounting a light-emitting element is composed of the upper sloped portion 44 and the lower sloped portion 45, the upper sloped portion 44 has a rectangular transverse cross section (rectangular opening) to prevent shaded regions, and the lower sloped portion 45 has a circular transverse cross section (circular opening) to ensure an equidistance in all directions from the light-emitting element to the wall surface to ensure uniform light reflection from all directions. However, the present invention is not limited to the structure described above.

In another embodiment, the optical device substrate 1″ can be structured such that the transverse cross section of the optical device substrate 1″ decreases toward a lower end (the bottom) thereof.

That is, the lower part of the optical device substrate 1′ illustrated in FIGS. 3A through 3C may be structured such that the outer peripheral edges of the bottom of the optical device substrate 1″ are chamfered as denoted by reference numeral 20 in FIG. 3A. That is, the transverse cross section of a lower portion of the optical device substrate 1″ gradually decreases toward the bottom. That is, the outer contour of the lower portion of the optical device substrate 1′ is tapered to the bottom.

Referring to FIG. 3B, the four edges of the lower end of the optical device substrate 1″ are obliquely cut away (chamfered).

With the structure in which the lower portion of the optical device substrate 1″ has a tapered structure in which the transverse cross section decreases toward the bottom, when arranging multiple optical device packages 100 on a panel to form a light source module, the optical device packages 100 can be more densely arranged. This can be achieved by the effect of reducing an adhesive-applied area of each of the optical device substrates 1″.

Although an embodiment in which the edges of the lower part of the optical device substrate 1″ are chamfered has been described hereinabove to obtain the tapered outer profile of the lower part of the optical device substrate, the present invention is not limited thereto. The outer surface of the lower part of the optical device substrate may have a stair-step shape. That is, any outer profile is possible as long as the profile enables the optical device substrates to be densely arranged.

In an embodiment, the optical device substrate 1″ has an insulating member 70 provided at a lower portion thereof.

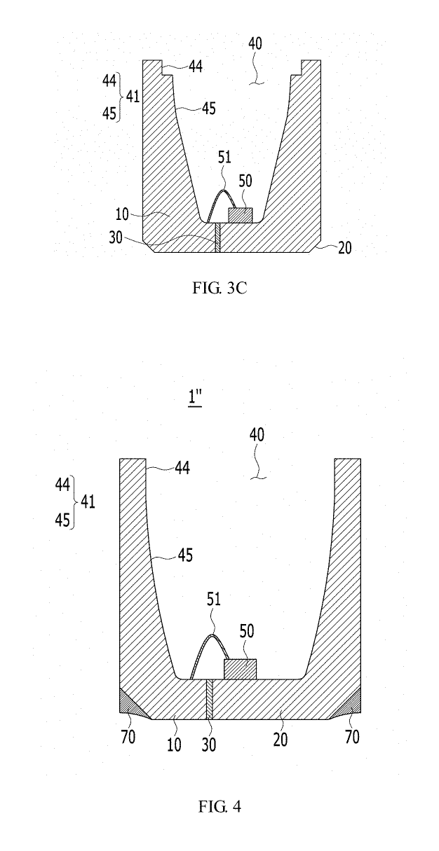

FIG. 4 illustrates a state in which the optical device substrate 1″ according to the third preferred embodiment of the present invention is provided with an insulating member. As illustrated in FIG. 4, the optical device substrate 1″ has the insulating member 70.

The insulating member 70 has a vertical surface, an oblique surface, and a curved surface. For example, referring to FIG. 4, the vertical surface of the insulating member 70 is flush with the side surface of the optical device substrate 1″, the oblique surface is in contact with the chamfered surface of the lower edge of the optical device substrate 1″, and the curve surface is a surface connecting the lower end of the vertical surface and the lower end of the oblique surface.

That is, the transverse cross section of the insulating member 70 has an overall D shape in which the right upper part of D is cut to have the oblique flat surface.

The insulating member 70 provided in the optical device substrate 1″ provides an adhesive accommodating space because the bottom surface of the insulating member 70 has a curved contour. Therefore, a gap is formed between the curved surface (lower surface) of the insulating member 70 and the upper surface of a panel when the optical device substrate 1″ is attached to the panel using an adhesive. When the optical device substrate 1″ is pressed to be securely fixed to the surface of the panel, the adhesive that is applied to the bottom surface of the optical device substrate 1″ is pressed out to enter into the gap formed under the curved surface of the insulating member 70.

In more detail, when multiple optical device packages 100 are attached to a single panel by using an adhesive such as a solder paste, in a case where the amount of the solder paste applied to the bottom surfaces of the optical device packages 100 is excessive, the solder paste is pressed out from the underside of the optical device substrate 1″ and rises along the side surface of the optical device substrate 1′. In this case, the solder paste that is pressed outside is likely to spread to cover the exposed portion of the vertical insulating layer 30, resulting in a short circuit.

At this time, the lower surface (curved surface) of the insulating member 70 that is in contact with the chamfered edge of the optical device substrate 1″ and is flush with the side surface of the optical device substrate 1″ provides the space thereunder for accommodating the excessive solder paste, thereby preventing a short circuit.

In the description hereinabove, although the insulating member 70 is provided at the lower end of the outer periphery of the optical device substrate 1″ according to the third preferred embodiment, the present invention is not limited thereto. That is, the insulating member 70 can also be provided to the optical device substrate 1 or 1′ by appropriately shaping a lower portion of the optical device substrate 1 or 1′.

Optical Device Package 100 Including Optical Device Substrate 1 According to First Embodiment

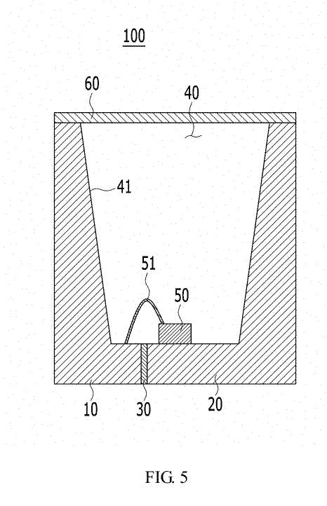

Herein below, an optical device package 100 including the optical device substrate 1 according to the first embodiment of the present invention will be described with reference to FIG. 5.

The optical device package 100 has the same structure as the optical device substrate 1 according to the first embodiment of the present invention, except for a light emitting element 50 and a light transmitting member 60. Therefore, like elements are denoted by like reference numerals, and a detailed description of the previously described elements will be omitted here.

FIG. 5 is a cross-sectional view of the optical device package 100 including the optical device substrate 1 according to the first embodiment of the present invention.

The optical device package 100 includes an optical device substrate 1, a light-emitting element 50, and a light transmitting member 60, in which the optical device substrate 1 includes first and second metal members 10 and 20, a vertical insulating layer 30 disposed between the first metal member 10 and the second metal member 20 in a transverse direction to electrically isolate the first metal member 10 and the second metal member 20 from each other, and an optical element cavity 40.

The light emitting element 20 is mounted inside the optical element cavity 40.

A lower portion of the light emitting element 50 is bonded onto the second metal member 20, and a wire 51 connected to an upper portion of the light emitting element is bonded to the first metal member 10.

The upper end of the optical element cavity 40 is covered by the light-transmitting member 60. The light transmitting member 60 is made of a light permeable material such as glass or quartz.

In the optical element cavity 40 formed in the optical device substrate 1, the light emitting element 50 is mounted. The light transmitting member 60 covers the optical element cavity 40. Therefore, light emitted from the light emitting element 50 passes around the sloped wall surface of the optical element cavity and transmits through the light transmitting member 60.

In other words, the optical device package 100 is formed by mounting the light emitting element 50 in the optical element cavity 40 and covering the optical device substrate 1 with the light transmitting member 600.

The light emitted from the light-emitting element 50 is reflected from the sloped wall surface 41 of the optical element cavity 40.

As described above, the surface roughness Ra of the sloped wall surface 41 of the optical element cavity 40 is controlled to fall within a range of 1 nm≤Ra≤100 nm.

The optical cavity package 100 including the optical device substrate 1 is formed such that the sloped wall surface 41 of the optical element cavity 40 has a surface roughness Ra in a range of 1 nm≤Ra≤100 nm. That is, the sloped wall surface 41 is formed to ensure a high surface reflection.

The surface roughness Ra of the sloped wall surface 41 defining the optical element cavity 40 can be measured by scanning regions each having a 10 μm×10 μm size one after another with a probe in a non-contact mode. The value of the surface roughness Ra is obtained by measuring the surface roughness with a surface roughness tester (model name: TT-AFM, manufactured by AFM Workshop Company).

The improvement in the surface roughness Ra over conventional arts can be confirmed with reference to FIG. 5.

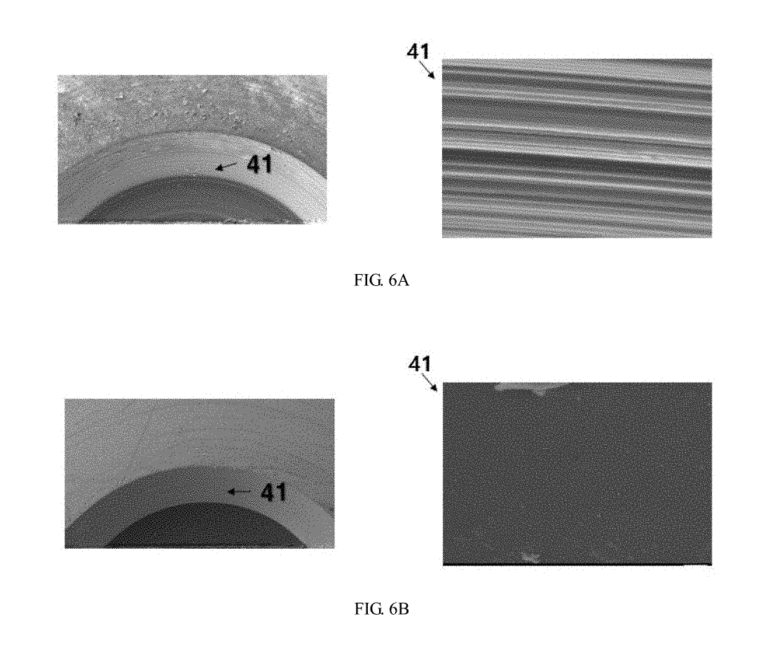

FIG. 6A is a photograph illustrating the surface roughness Ra of a sloped wall surface 41 of an optical element cavity 40 of a conventional optical device substrate.

As illustrated in FIG. 6A, strip patterns are shown on the sloped wall surface 41 of the optical element cavity 40. It means that the sloped wall surface 41 of the optical device cavity 40 has a high surface roughness (Ra).

Therefore, due to the high surface roughness Ra of the sloped wall surface 41 of the optical element cavity 40, the surface reflection of the sloped wall surface 41 is reduced.

FIG. 6B is a photograph illustrating the surface roughness Ra of a sloped surface 41 of an optical element cavity 40 of an optical device substrate according to one embodiment of the present invention. The surface roughness Ra is measured with a surface roughness tester.

As illustrated in FIG. 6B, the sloped wall surface 41 defining the optical element cavity 40 in the optical device substrate according to the present invention is smooth and has no specific pattern unlike the sloped wall surface 41 of FIG. 6A.

That is, when the surface roughness Ra of the sloped wall surface 41 of the optical element cavity 40 satisfies the condition “1 nm≤Ra≤100 nm”, the smooth sloped wall surface 41 illustrated in FIG. 6B is formed to ensure a high surface reflectance inside an optical element cavity.

In one embodiment of the present invention, the optical device package 100 is manufactured by installing the light-emitting element 50 and the light-transmitting layer 60 on the optical device substrate 1 according to the first preferred embodiment of the present invention. However, the optical device package 100 according to the present invention is not limited thereto. The optical device package 100 according to the present invention can be manufactured by installing the light-emitting element 50 and the light-transmitting member 60 on any one of the optical device substrates 1, 1′, and 1″ according to the first, second, and third preferred embodiments, or on any other suitable optical device substrate.

The optical device substrates 1, 1′, and 1″ and the optical device package 100 according to the preferred embodiments of the present invention have an advantage that when any of them is employed in a UV exposure apparatus, it is possible to reduce diffused reflection (irregular reflection) to minimize the loss of UV light and to ensure a sufficient UV optical path because the sloped wall surface 41 of the optical element cavity 40 has an improved surface roughness.

Therefore, when the optical device package 100 according to the present invention is manufactured by using any one of the optical device substrates 1, 1′, and 1″, since the sloped wall surface 41 of the optical element cavity 40 of the optical device substrate 1, 1′, or 1″ has the surface roughness Ra within a range of minimizing the loss of light, the light efficiency of the optical device package 100 can be increased.

In addition, since the optical device substrates 1, 1′, and 1″ according to the present invention are structured such that a lower end portion of the substrate has a transverse cross section that gradually decreases toward the lower end thereof, the adhesive-applied bottom surface area of the optical device substrate is reduced. Therefore, it is possible to arrange a large number of optical device packages 100 in a closely arranged manner.

In addition, since the insulating layer 42 and the metal reflective layer 43 are formed on the sloped wall surface 41 of the optical element cavity 40 formed in any of the optical device substrates 1, 1′, and 1″, it is possible to eliminate a light reflection hindering factor, thereby increasing the surface reflectance of the sloped wall surface 41 of the optical element cavity 40.

In addition, since the optical device substrates 1, 1′, and 1″ according to the present invention have the optical element cavity 40 defined by the upper sloped wall surface 44 having a rectangular transverse cross section (rectangular opening) and the lower sloped wall surface 45 having a circular transverse cross section (circular opening), it is possible to effectively condense the light emitted from the light-emitting element 50 by using the conical or cylindrical wall surface of the lower portion of the optical element cavity and to effectively output the light without causing a shaded region by using the cube-shaped wall surface of the upper portion of the optical element cavity 40. Therefore, when a plurality of optical device packages 100 are mounted within a light source module, it is possible to prevent shaded regions.

Although the preferred embodiments of the present invention have been described above, those skilled in the art would appreciate that various changes, modifications, alterations are possible without departing from the technical spirit and scope of the invention defined in the appended claims.

1. An optical device substrate comprising:
first and second metal members;
a vertical insulating layer disposed between the first metal member and the second metal member in a transverse direction to electrically insulate the first metal member and the second metal member from each other; and
an optical element cavity,
wherein a sloped wall surface defining the optical element cavity has a surface roughness Ra within a range of 1 nm≤Ra≤100 nm.

2. The optical device substrate according to claim 1, wherein a lower portion of the optical device substrate is structured such that a transverse cross section thereof decreases toward a lower end of the optical device substrate.

3. An optical device substrate comprising:
first and second metal members;
a vertical insulating layer disposed between the first metal member and the second metal member in a transverse direction to electrically insulate the first metal member and the second metal member from each other; and
an optical element cavity,
wherein an insulating layer and a metal reflective layer are formed on a sloped wall surface defining the optical element cavity.

4. An optical device substrate comprising:
first and second metal members;
a vertical insulating layer disposed between the first metal member and the second metal member in a transverse direction to electrically insulate the first metal member and the second metal member from each other; and
an optical element cavity,
wherein a sloped wall surface defining the optical element cavity includes an upper sloped portion having a rectangular transverse cross section corresponding to a rectangular opening and a lower sloped portion having a circular transverse cross section corresponding to a circular opening.

5. The optical device substrate according to claim 4, wherein the upper sloped portion and the lower sloped portion of the sloped wall surface defining the optical element cavity has a surface roughness Ra within a range of 1 nm≤Ra≤100 nm.

6. An optical device package comprising:
an optical device substrate including first and second metal members, a vertical insulating layer disposed between the first metal member and the second metal member in a transverse direction to electrically insulate the first metal member and the second metal member from each other, and an optical element cavity;
a light-emitting element mounted inside the optical element cavity; and
a light transmitting member configured to cover the optical element cavity, and
wherein a sloped wall surface defining the optical element cavity has a surface roughness Ra within a range of 1 nm≤Ra≤100 nm.
